(19) United States
(12) Patent Application Publication
(10) Pub. No.: US 2009/0168359 A1
(43) Pub. Date: Jul. 2, 2009

(54) HEAT SINK

(75) Inventors: CHENG-LIN YAN, Shenzhen (CN); WAN-YI CHOU, Tu-Cheng (TW)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/964,928

(22) Filed: Dec. 27, 2007

(51) Int. Cl. H05K 7/20

(52) U.S. Cl. 361/710

(57) ABSTRACT

A heat sink includes a plurality of parallel fins (100). Each fin includes a main body (10) and at least one flange (20, 22) bending from the main body. At least one locking device (30) is formed on the at least one flange of the fin. The locking device includes an ear (40) extending outwardly from an outer edge of the at least one flange, a locking hole (50) defined in the at least one flange, and a locking tab (60) extending aslant from an inner side of the ear adjacent to the locking hole towards the main body of the fin. The ear of one fin is received in the locking hole of a neighboring fin, and the locking tab of the one fin abuts the main body of the neighboring fin.

### BACKGROUND OF THE INVENTION

1. Field of the Invention

The present invention relates to a heat sink, and more particularly relates to a heat sink having high density fins.

2. Description of related art

With the continuing development of the electronic technology, electronic packages such as CPUs (central processing units) are generating more and more heat which requires immediate dissipation. A heat sink is usually mounted on the electronic component for dissipating heat of the electronic packages.

Typical heat sinks are often integrally made by extruding aluminum. The kind of integral heat sink has a base and a plurality of spaced fins extending upwardly from the base. However, the width-to-height ratio of the heat sink is limited by the extruding process. Thus, the effective heat-dissipating area of the heat sink is restricted. In order to overcome the extruding problem, a combined heat sink is provided. This kind of heat sink has a plurality of fin being separately formed and then assembled onto a base. However, the combined heat sink fins are usually assembled to the base one by one through welding, which is complicated and time consuming.

For the foregoing reasons, therefore, there is a need in the art for a heat sink which overcomes the above-mentioned problems.

### SUMMARY OF THE INVENTION

According to a preferred embodiment of the present invention, a heat sink includes a plurality of parallel fins. Each fin includes a main body and at least one flange bending from the main body. At least one locking device is formed on the at least one flange of the fin. The locking device includes an ear extending outwardly from an outer edge of the at least one flange, a locking hole defined in the at least one flange, and a locking tab extending aslant from an inner side of the ear adjacent to the locking hole towards the main body of the fin. The ear of one fin is received in the locking hole of a neighboring fin, and the locking tab of the one fin abuts the main body of the neighboring fin.

Other advantages and novel features of the present invention will be drawn from the following detailed description of the preferred embodiments of the present invention with attached drawings, in which:

### BRIEF DESCRIPTION OF THE DRAWINGS

Many aspects of the present heat sink can be better understood with reference to the following drawings. The components in the drawings are not necessarily drawn to scale, the emphasis instead being placed upon clearly illustrating the principles of the present heat sink. Moreover, in the drawings, like reference numerals designate corresponding parts throughout the several views.

FIG. 1 is an isometric, assembled view of a heat sink in accordance with a preferred embodiment of the present invention;

FIG. 2 is an isometric view of the heat sink, with two fins thereof being separated;

FIG. 3 is an enlarged view of a circled portion III of FIG. 1; and

FIG. 4 is an enlarged view of a circled portion IV of FIG. 1.

### DETAILED DESCRIPTION OF THE INVENTION

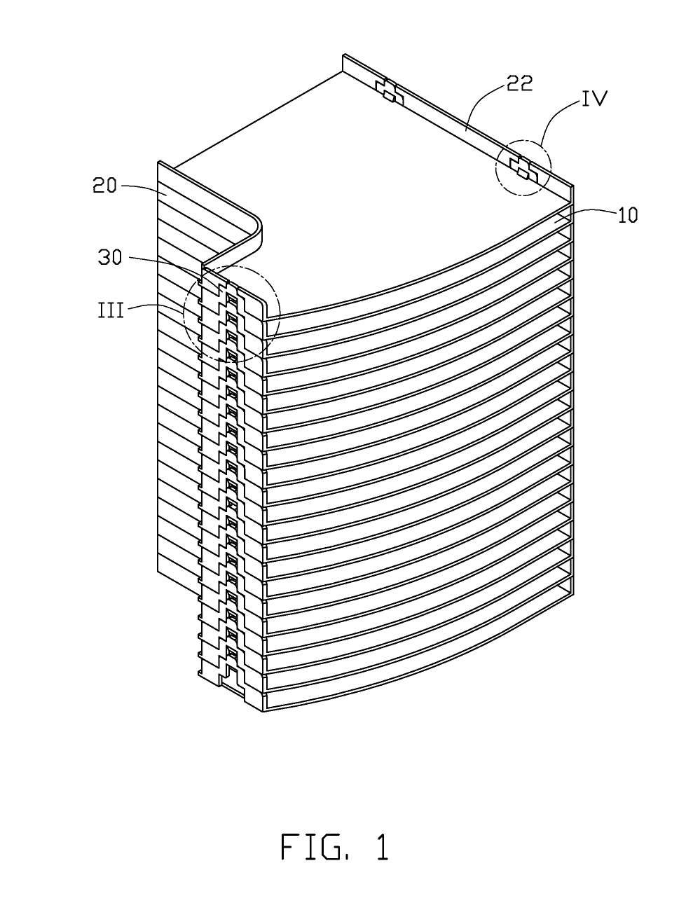

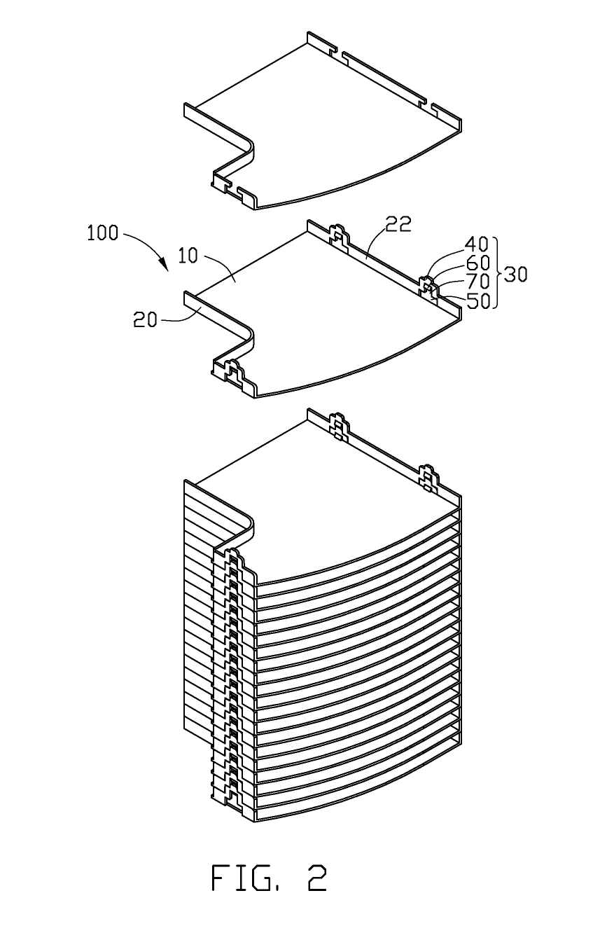

Referring to FIGS. 1 and 2, a heat sink according to a preferred embodiment includes a plurality of stacked fins 100. The fins 100 are parallel to each other. A flow channel is defined between every two neighboring fins 100.

The fins 100 are stacked along a longitudinal direction. Each fin 100 includes a planar-shaped main body 10 and a pair of flanges 20, 22 bending from the main body 10. The two flanges 20, 22 extend perpendicularly and upwardly from two opposite sides (i.e., a front side and a rear side) of the main body 10, respectively. Each flange 20, 22 forms at least one locking device 30 to lock the fins 100 together. In this embodiment, the front flange 20 includes one locking device 30 formed adjacent to a right side thereof, whilst the rear flange 22 includes a pair of locking device 30 arranged at a left side and a right side thereof, respectively. It is to be understood that the position, the number of the locking devices 30 can be changed according to the size or the shape of the fin 100, thus to firmly combine the fins 100 together.

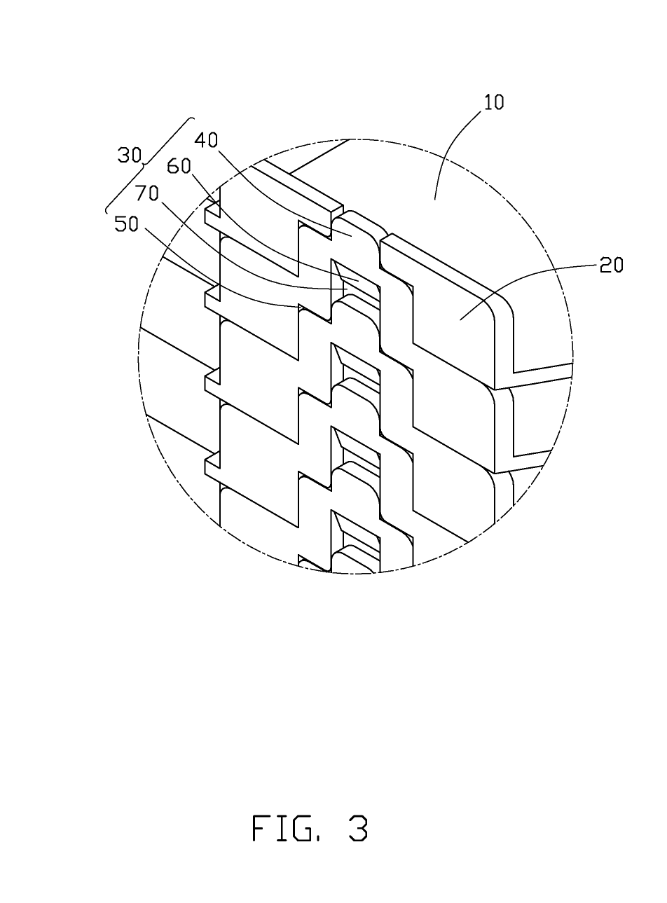

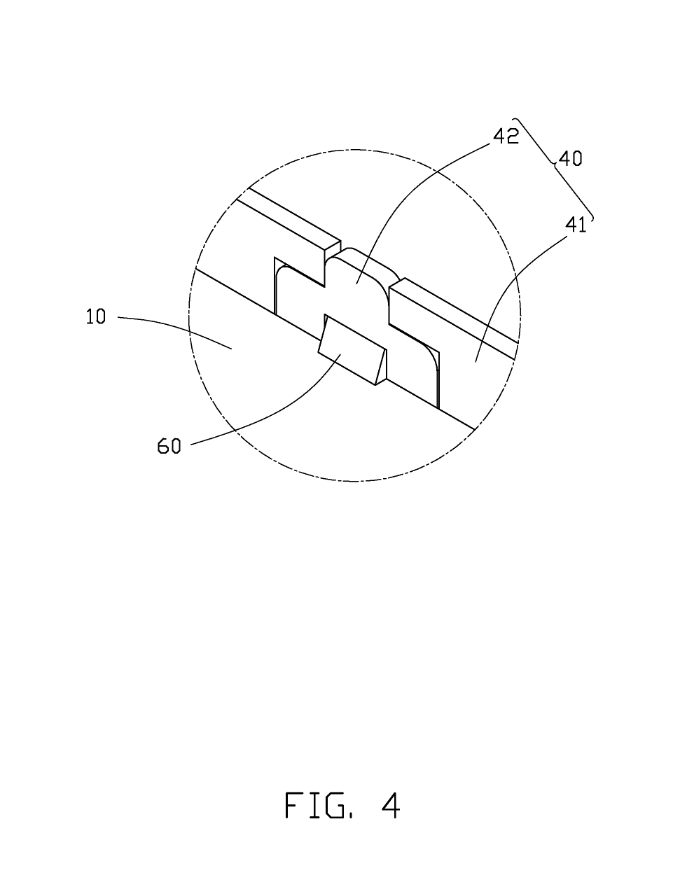

Referring to FIGS. 3-4, the locking device 30 formed on each flange 20, 22 of the fin 100 is the same as the others. Each locking device 30 includes an ear 40, a locking hole 50, and a locking tab 60. The ear 40 is integrally formed with the flange 20, 22 and extends outwardly from an outer edge of the flange 20, 22, and has a height being approximately the same as that of the flange 20, 22. Each ear 40 has an elongated rectangularly-shaped lower portion 42 connecting with the flange 20, 22 and a rectangularly-shaped upper portion 41. The upper portion 41 has a width being smaller than that of the lower portion 42, and extends upwardly from a middle of the lower portion 42. Thus the ear 40 has a step-shaped outer profile. The locking tab 60 extends aslant from the ear 40 of the flange 20, 22 towards the main body 10 of the fin 100. An upper end of the locking tab 60 connects to an inner side of the lower portion 42 of the ear 40 adjacent to the locking hole 50, and a lower end of the locking tab 60 is spaced from the inner side of the lower portion 42 of the ear 40. A through hole 70 is defined in the ear 40 corresponding to the locking tab 60. The locking hole 50 is defined in the flange 20, 22 corresponding to the ear 40. A size and a shape of the locking hole 50 is the same as that of the ear 40. The locking hole 50 communicates with the through hole 70.

In assembly, the fins 100 are arranged parallel to each other. The ear 40 of a lower fin 100 is received in the locking hole 50 of a neighboring upper fin 100, the locking tab 60 of the lower fin 100 abuts an upper surface of the main body 10 of the neighboring upper fin 100, as shown in FIG. 4. Thus the fins 100 are locked together. The locking tabs 60 of the lower fin 100 abut the neighboring upper fin 100 therefore preventing the lower fin 100 from releasing from the neighboring upper fin 100. On the other hand, since the ears 40 and the locking holes 50 are step-shaped, the ears 40 engage into the locking holes 50, thereby preventing the fins 100 from moving upwardly and thus keeping a suitable distance between neighboring fins 100 for improving heat dissipating efficiency of the heat sink. Thus the heat sink can have a simple locking structure to lock the fins 100 together. Accordingly assembly of the heat sink is simple and can be more quickly completed.

It is understood that the invention may be embodied in other forms without departing from the spirit thereof. Thus, the present example and embodiment are to be considered in all respects as illustrative and not restrictive, and the invention is not to be limited to the details given herein.

What is claimed is:

1. A heat sink comprising:
a plurality of parallel fins, each fin comprising a main body and at least one flange bending from the main body; and
at least one locking device forming on the at least one flange of the fin, the locking device comprising an ear extending outwardly from an outer edge of the at least one flange, a locking hole defined in the at least one flange, and a locking tab extending aslant from the ear towards the main body of the fin, the ear of one fin being received in the locking hole of a neighboring fin, and the locking tab of the one fin abutting the main body of the neighboring fin.

2. The heat sink of claim 1, wherein the locking tab is integrally formed with the ear of the fin, and a through hole is defined in the ear corresponding to the locking tab.

3. The heat sink of claim 2, wherein the locking hole communicates with the through hole.

4. The heat sink of claim 1, wherein the ear has a step-shaped outer profile, and the locking hole has the same shape and size as the ear.

5. The heat sink of claim 1, wherein the flange has a height the same as that of the ear.

6. The heat sink of claim 1, wherein each fin has a pair of flanges formed at two opposite sides thereof, the at least one locking device being formed on each of the flanges.

7. The heat sink of claim 1, wherein the ear includes a rectangularly-shaped lower portion and a rectangularly-shaped upper portion, the upper portion having a width smaller than the lower portion and extending outwardly from a middle of the lower portion, the locking tab extending aslant from an inner side of the lower portion adjacent to the locking hole.
